(19) United States
(12) Patent Application Publication
(10) Pub. No.: US 2025/0279340 A1
(43) Pub. Date: Sep. 4, 2025

(54) MULTI-CHIP SEMICONDUCTOR MODULE WITH BALANCED SWITCHING

(71) Applicant: SEMICONDUCTOR COMPONENTS INDUSTRIES, LLC, Scottsdale, AZ (US)

(72) Inventors: Seungwon IM, Bucheon (KR); Keunhyuk LEE, Suzhou (CN); Jonghwan BAEK, Gimpo-City (KR); Dukyong LEE, Bucheon (KR)

(73) Assignee: SEMICONDUCTOR COMPONENTS INDUSTRIES, LLC, Scottsdale, AZ (US)

(21) Appl. No.: 18/592,273

(22) Filed: Feb. 29, 2024

(51) Int. Cl. H01L 23/495; H01L 23/00; H01L 25/065

(52) U.S. Cl. CPC H01L 23/49575; H01L 23/4951; H01L 24/40; H01L 24/48; H01L 25/0652; H01L 2224/40145; H01L 2224/40175; H01L 2224/48149; H01L 2224/48177; H01L 2924/01029; H01L 2924/0665; H01L 2924/13091; H01L 2924/181

(57) ABSTRACT

In a general aspect, a semiconductor device assembly includes a substrate having a patterned metal layer disposed thereon, a first semiconductor die, the first semiconductor die disposed on a first portion of the patterned metal layer, and a second semiconductor die disposed on the first portion of the patterned metal layer. The assembly also includes a first electrical connection electrically coupling a second portion of the patterned metal layer with the first semiconductor die. and a second electrical connection electrically coupling the second portion of the patterned metal layer with the second semiconductor die. The second electrical connection is substantially electrically balanced with the first electrical connection.

### BACKGROUND

Packaged semiconductor device modules can include multiple semiconductor die. For example, a power semiconductor device module can include multiple semiconductor die implementing respective power transistors, such as power field-effect transistors that are coupled in a parallel arrangement, e.g., such that the power transistors operate, in combination, as a single switch. Such parallel-connected transistors in prior implementations can exhibit inconsistent switching behavior, e.g., differences in turn-on and turn-off timing. Such inconsistent switching behavior can, for example, adversely affect operating frequencies at which such device module can operate, adversely affect electrical operating efficiency, and/or adversely affect corresponding signal quality. For power modules including parallel-connected transistors, as transistor switching speeds increase, any associated switching behavior inconsistency between can, proportionally, have a greater impact on performance of an associated power module.

### SUMMARY

A semiconductor device module can include multiple semiconductor dies, such as a first semiconductor die including a first transistor, e.g. a first metal-oxide-semiconductor field-effect transistor (MOSFET), and a second semiconductor die including a second transistor, e.g., a second MOSFET. For instance, in some implementations the first transistor can be coupled in parallel with the second transistor, such that the first and second transistor operate as a single switch. The module can include signal connections (electrical connections) that are substantially electrically balanced. For instance, an electrical connection to a gate terminal of the first transistor can be substantially electrically balanced with an electrical connection to a gate terminal of the first transistor. In some implementation, respective electrical connections to a source terminal of the first transistor and a source terminal of the second transistor can be substantially electrically balanced, and/or respective electrical connections to a drain terminal of the first transistor and a drain terminal of the second transistor can be substantially electrically balanced.

In a general aspect, a semiconductor device assembly includes a substrate having a patterned metal layer disposed thereon, a first semiconductor die, the first semiconductor die disposed on a first portion of the patterned metal layer, and a second semiconductor die disposed on the first portion of the patterned metal layer. The assembly also includes a first electrical connection electrically coupling a second portion of the patterned metal layer with the first semiconductor die. and a second electrical connection electrically coupling the second portion of the patterned metal layer with the second semiconductor die. The second electrical connection is substantially electrically balanced with the first electrical connection.

In another general aspect, a semiconductor device assembly includes a substrate having a patterned metal layer disposed thereon, a first semiconductor die including a first transistor, and a second semiconductor die including a second transistor. The first semiconductor die and the second semiconductor die are respectively disposed on a first portion of the patterned metal layer. The assembly further includes a conductive clip implementing a first electrical connection between a second portion of the patterned metal layer and a gate terminal of the first transistor, and a second electrical connection between the second portion of the patterned metal layer and a gate terminal of the second transistor. The second electrical connection is substantially electrically balanced with the first electrical connection.

In another general aspect, a semiconductor device assembly includes a substrate having a patterned metal layer disposed thereon, a first semiconductor die disposed on a first portion of the patterned metal layer, and a second semiconductor die disposed on the first portion of the patterned metal layer. The first semiconductor die includes a first transistor, and the second semiconductor die includes a second transistor. The assembly also includes a first bond wire implementing a first electrical connection between a second portion of the patterned metal layer and a gate terminal of the first transistor, and a second bond wire implementing a second electrical connection between the second portion of the patterned metal layer and a gate terminal of the second transistor. The second electrical connection is substantially electrically balanced with the first electrical connection.

### BRIEF DESCRIPTION OF THE DRAWINGS

FIG. 1 is a block diagram that schematically illustrates an example multi-chip semiconductor device assembly.

FIG. 2 is a diagram that illustrates an example multi-chip semiconductor device assembly.

FIG. 3 is a diagram that illustrates another example multi-chip semiconductor device assembly.

FIG. 4 is a diagram that illustrates yet another example multi-chip semiconductor device assembly.

FIG. 5 is a diagram that illustrates an example multi-substrate panel.

FIG. 6 is a flowchart illustrating an example method for producing a multi-chip semiconductor device assembly, such as the example assemblies of FIGS. 2 to 4.

FIG. 7 is a flowchart illustrating another example method for producing a multi-chip semiconductor device assembly, such as the example assemblies of FIGS. 2 to 4.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

At least one technical problem with electronic devices including multiple semiconductor die can be switching imbalance between parallel-connected transistors. For instance, turn-on and turn-off for a transistor of a plurality of parallel-connected transistors may be delayed as compared to turn-on and turn-off of another transistor of the parallel-connected transistors. Such switching imbalance can affect performance of an associated power module, such as limiting a frequency of operation of the device, affecting signal timing in an associated system in which the power module is included, reducing power use efficiency due to excess switching current, and/or causing signal ringing. Such performance impacts can be proportionally greater for power modules including transistors with higher switching speeds and/or higher operating power ratings, such as silicon carbide (SiC) field-effect transistors (FETs).

Power modules can include a plurality of semiconductor die implementing respective power devices. For instance, a power module can include a plurality of parallel connected power transistors, where each power transistor is included in a respective semiconductor die. Such power modules can include a direct-bonded metal (DBM) substrate, such as a direct-bonded copper (DBC) substrate. A DBM or DBC substrate can include a ceramic material layer with direct-bonded metal, for example, a patterned metal layer including one or more patterned metal layer portions disposed on at least one side of the ceramic material layer. In the example above, the plurality of semiconductor die, for example, respective drain terminals of the power transistors, can be disposed on, and electrically coupled with a first patterned metal layer portion of the substrate. A conductive clip can electrically couple the semiconductor die, for example, respective source terminals of the power transistors, with a second patterned metal layer portion of the substrate. Additional elements can be included, such as wire bonds, signal leads, power terminals, and/or a molding compound. For instance, in the example above, wire bonds can be used to couple a signal pin of the module with a third patterned metal layer portion of the substrate, and to couple the third patterned metal layer portion with gate terminals of the parallel connected power transistors.

One technical solution to the aforementioned technical problem is to reduce or eliminate conduction path differences, such as for gate signal conduction paths, source conduction signal paths and/or drain signal conduction paths, e.g., for parallel-connected transistors. For example, signal conduction paths for parallel-connected transistors can be electrically balanced, or substantially electrically balanced. For instance, respective gate signal conduction paths can be substantially electrically balanced, as can be respective source signal conduction paths and/or respective drain signal conduction paths. As used herein, electrically balanced, or substantially electrically balanced refers to signal conduction paths that are designed and produced to have matching electrical conduction characteristics, such as impedance, signal travel time, electrical path length, and so forth. While the objective is to achieve matching electrical conduction characteristics, some negligible or minor variations may occur, e.g., due to design limitations and/or processing variations (tolerances). Similarly, conduction paths (e.g., bond wires) may be described has having equal (or same) lengths, or substantially equal (or substantially same) lengths. Again, while the objective is to achieve equal or same lengths, some negligible or minor variations may occur, e.g., due to manufacturing tolerances.

At least one technical effect of this this technical solution can be reduced and/or eliminated switching imbalance between transistors of parallel-connected transistors of a power module. At least one benefit of this technical solution is improved performance of semiconductor device modules (e.g., semiconductor device assemblies) that including parallel-connected devices, such as parallel-connected transistors. This improved performance can include increased operating frequency, improved signal quality (e.g., reduced or eliminated ringing), and/or improved power efficiency.

At least one other technical solution for the aforementioned technical problem is the use of direct-lead attachment for signal pins that are used for a gate control signal. This can also reduce parasitic impedance as compared to prior implementations. At least one technical effect of this this technical solution can be reduced and/or eliminated switching imbalance between transistors of parallel-connected transistors of a power module. At least one benefit of this technical solution is also improved performance of semiconductor device modules (e.g., semiconductor device assemblies) that including parallel-connected devices, such as parallel-connected transistors. This improved performance can include increased operating frequency, improved signal quality (e.g., reduced or eliminated ringing), and/or improved power efficiency.

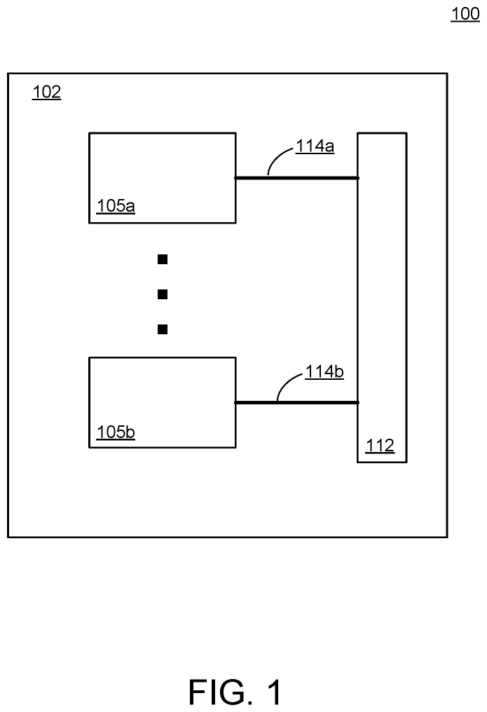

FIG. 1 is a block diagram that schematically illustrates an example multi-chip semiconductor device assembly (power module 100). The power module 100 includes a plurality of semiconductor die, including a semiconductor die 105a and a semiconductor die 105b. As indicated in FIG. 1, in some implementations, additional semiconductor die can be included. The semiconductor die 105a and the semiconductor die 105b are disposed on a substrate 102, such as on a portion of a patterned metal layer of the substrate 102 (not shown in FIG. 1).

In some implementations, the substrate 102 can be a direct-bonded metal (DBM) substrate, such as a direct-copper (DBC) substrate. That is, the substrate 102 can include a ceramic layer (e.g., ceramic substrate portion) having a patterned metal layer disposed on a primary surface of the ceramic layer. For instance, the patterned metal layer can include a plurality of separate (distinct, etc.) patterned metal layer portions, such as those described herein. For instance, in the example of FIG. 1, the substrate 102 includes a patterned metal layer portion 112 disposed on the substrate 102. An electrical connection 114a can electrically couple the patterned metal layer portion 112 with the semiconductor die 105a. For instance, the electrical connection 114a can electrically couple the patterned metal layer portion 112 with a gate terminal included in the semiconductor die 105a. As further shown in FIG. 1 an electrical connection 114b can electrically couple the patterned metal layer portion 112 with the semiconductor die 105b. For instance, the electrical connection 114b can electrically couple the patterned metal layer portion 112 with a gate terminal included in the semiconductor die 105b.

In this example, the electrical connection 114a and the electrical connection 114b are substantially electrically balanced, such as described herein. In some implementations, the power module 100 can include additional substantially electrically balanced electrical connection to other respective terminals of the semiconductor die 105a and the semiconductor die 105b, e.g., source terminals and/or drain terminals of respective transistors. Such use of electrically balanced (substantially electrically balanced) electrical connections can reduce and/or eliminate switching imbalance and associated performance impacts, e.g., for parallel connected devices.

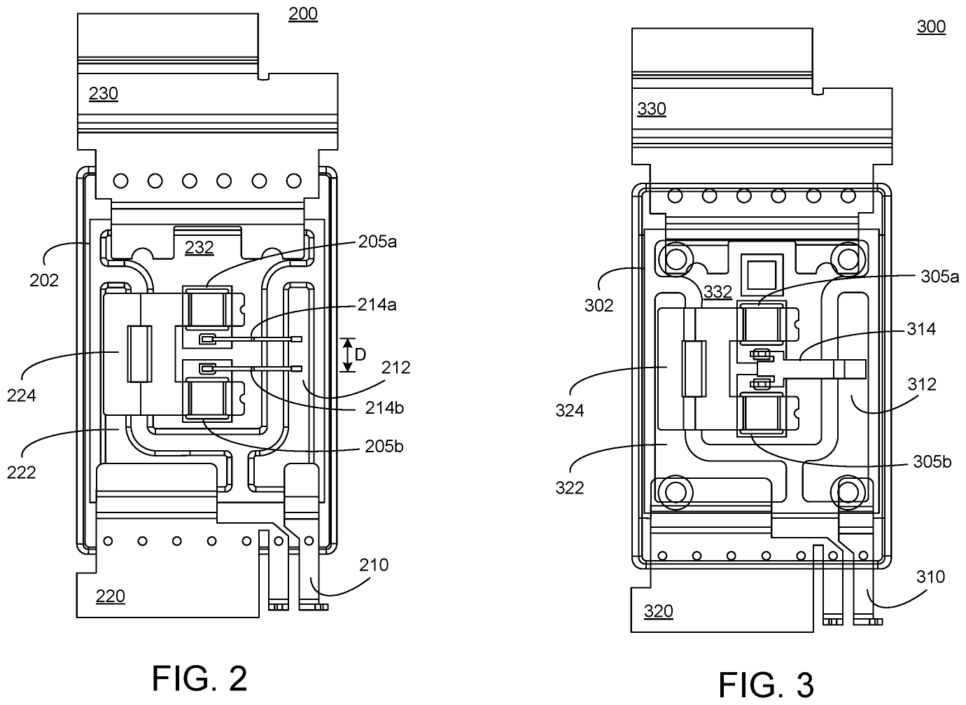

FIG. 2 is a diagram that illustrates an example multi-chip semiconductor device assembly. That is, FIG. 2 is a diagram illustrating an example implementation of a power module 200 including a plurality of parallel-connected power transistors. As shown in FIG. 2, the power module 200 includes a semiconductor die 205a, and a semiconductor die 205b. In this example, each of the semiconductor die 205a and the semiconductor die 205b includes a respective power transistor, such as a respective vertical FET. As shown in FIG. 2, a gate signal lead 210 can be coupled, via direct-lead attach (DLA), with a patterned metal layer portion 212 of a patterned metal layer disposed on a ceramic substrate 202 of the power module 200. For instance, the gate signal lead 210 can be coupled with the patterned metal layer portion 212 via solder, a laser-welded bond, a brazed bond, or a sintered bond, as some examples. As compared to prior approaches, the DLA approach of FIG. 2 can eliminate one more wire bonds between the gate signal lead 210 and the patterned metal layer portion 212, which can reduce associated parasitic impedance.

As further shown in FIG. 2, a wire bond 214a electrically couples the patterned metal layer portion 212 with a gate terminal of the FET of the semiconductor die 205a, and a wire bond 214b electrically couples the patterned metal layer portion 212 with a gate terminal of the FET of the semiconductor die 205b. In this example, the wire bond 214a and the wire bond 214b, within manufacturing tolerances of an associated assembly process, are a same length (substantially a same length). Accordingly, the only difference in conduction path length for the gate terminal connection to the semiconductor die 205a and the gate terminal connection to the semiconductor die 205b in this example is a distance D of the patterned metal layer portion 212. As parasitic impedance of the distance D of the patterned metal layer portion 212 may be negligible, switching imbalance between the respective transistors of the semiconductor die 205a and the semiconductor die 205b can be reduced as compared to prior implementations, or can be effectively eliminated, e.g., where any switching imbalance is negligible. That is, the wire bond 214a and the wire bond 214b can implement substantially electrically balanced respective signal conduction paths between the patterned metal layer portion 212 and gate terminals of the transistors of the semiconductor die 205a and the semiconductor die 205b.

The power module 200 further includes a source power terminal 220 that is coupled, via DLA, with a patterned metal layer portion 222 that is disposed on the ceramic substrate 202. The patterned metal layer portion 222 is coupled with respective sources terminals of the semiconductor die 205a and the semiconductor die 205b via a conductive clip 224. The conductive clip 224 can be coupled with the patterned metal layer portion 222, the semiconductor die 205a and the semiconductor die 205b using solder, or sintering, as two examples. Accordingly, the conductive clip 224 can implement respective substantially electrically balanced conduction paths from the patterned metal layer portion 222 (or the source power terminal 220) to the respective source terminals of the transistors of the semiconductor die 205a and the semiconductor die 205b.

Similarly, the power module 200 also includes a drain power terminal 230 that is coupled, via DLA with a patterned metal layer portion 232 that is disposed on the ceramic substrate 202. The patterned metal layer portion 232 is coupled with respective drain terminals of the semiconductor die 205a and the semiconductor die 205b via back sides of the semiconductor die. Accordingly, the drain power terminal 230 and the patterned metal layer portion 232 can implement substantially electrically balanced conduction paths to respective drain terminals of the transistors of the semiconductor die 205a and the semiconductor die 205b.

FIG. 3 is a diagram that illustrates another example multi-chip semiconductor device assembly. That is, FIG. 3 is a diagram illustrating another example implementation of a power module 300 including a plurality of parallel-connected power transistors. As shown in FIG. 3, the power module 300 includes a semiconductor die 305a, and a semiconductor die 305b. In this example, each of the semiconductor die 305a, and the semiconductor die 305b includes a respective power transistor, such as a respective vertical FET. As shown in FIG. 3, a gate signal lead 310 can be coupled, via DLA, with a patterned metal layer portion 312 disposed on a ceramic substrate 302 of the power module 300. For instance, the gate signal lead 310 can be coupled with the patterned metal layer portion 312 via solder, a laser-welded bond, a brazed bond, or a sintered bond, as some examples. As compared to prior approaches, and as with the power module 200 of FIG. 2, the DLA approach of FIG. 3 eliminates a wire bond between the gate signal lead 310 and the patterned metal layer portion 312, which can reduce associated parasitic impedance.

As further shown in FIG. 3, a conductive clip 314 electrically couples the patterned metal layer portion 312 with a gate terminal of the FET of the semiconductor die 305a, and a gate terminal of the FET of the semiconductor die 305b. In this example, the respective conduction path distances from the gate signal lead 310 and the gate terminal of the semiconductor die 305a and the gate terminal of the semiconductor die 305b, within manufacturing tolerances of an associated assembly process, are a same length. Accordingly, parasitic impedances differences between the respective gate conduction path are negligible, such as approaching zero. Therefore, switching imbalance between the respective transistors of the semiconductor die 305a and the semiconductor die 305b can be reduced, or effectively eliminated as compared to prior approaches. That is, the conductive clip 314 can implement substantially electrically balanced signal conduction paths between the patterned metal layer portion 312 and respective gate terminals of the transistors of the semiconductor die 305a and the semiconductor die 305b.

The power module 300 further includes a source power terminal 320 that is coupled, via DLA, with a patterned metal layer portion 322 that is disposed on the ceramic substrate 302. The patterned metal layer portion 322 is coupled with respective sources terminals of the semiconductor die 305a and the semiconductor die 305b via a conductive clip 324. The conductive clip 324 can be coupled with the patterned metal layer portion 322, the semiconductor die 305a and the semiconductor die 305b using solder, or sintering, as two examples. Accordingly, the conductive clip 324 can implement substantially electrically balanced conduction paths from the patterned metal layer portion 322 (or from the source power terminal 320) to the respective source terminals of the transistors of the semiconductor die 305a and the semiconductor die 305b.

Similarly, the power module 300 also includes a drain power terminal 330 that is coupled, via DLA, with a patterned metal layer portion 332 that is disposed on the ceramic substrate 302. The patterned metal layer portion 332 is coupled with respective drain terminals of the semiconductor die 305a and the semiconductor die 305b via back sides of the semiconductor die. Accordingly, the drain power terminal 330 and the patterned metal layer portion 332 can implement substantially electrically balanced conduction paths to respective drain terminals of the transistors of the semiconductor die 305a and the semiconductor die 305b.

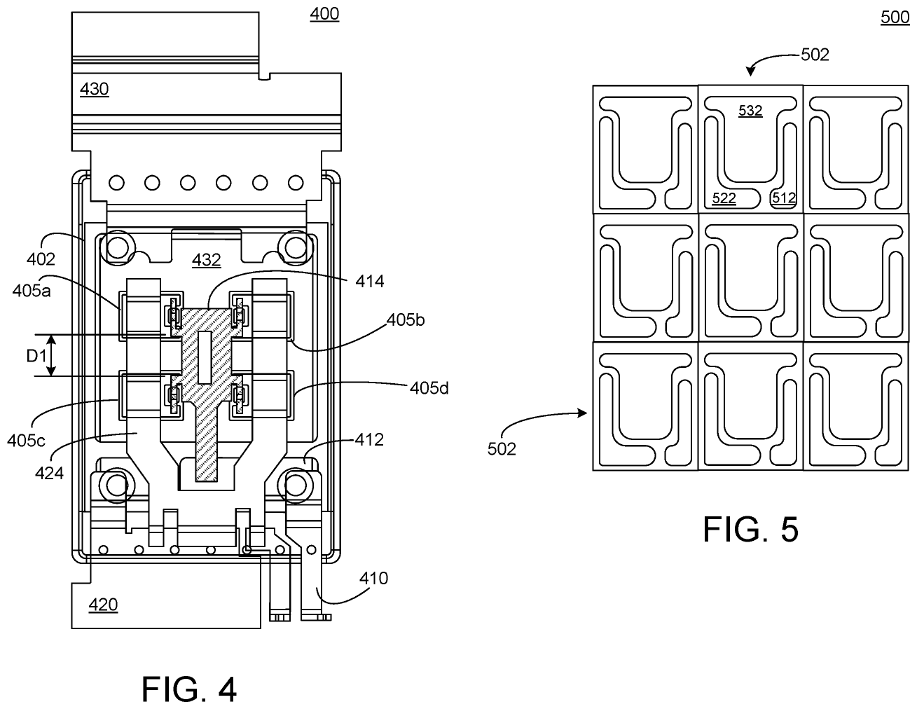

FIG. 4 is a diagram that illustrates yet another example multi-chip semiconductor device assembly. That is, FIG. 4 is a diagram illustrating another example implementation of a power module 400 including a plurality of parallel-connected power transistors. As shown in FIG. 4, the power module 400 includes a semiconductor die 405a, a semiconductor die 405b, semiconductor die 405c, and a semiconductor die 450d. In this example, each of the semiconductor die 405a, the semiconductor die 405b, the semiconductor die 405c, and the semiconductor die 405d includes a respective power transistor, such as a respective vertical FET. The example of FIG. 4 can reduce system costs, as implementing four parallel transistors in the power module 400, as compared with two transistors of the other examples, This can reduce, for example, by half, the number power modules used in a corresponding system, as well as reduce corresponding area of a circuit board, such as printed circuit board, used in such a system.

As shown in FIG. 4, a gate signal lead 410 can be coupled, using DLA, with a patterned metal layer portion 412 disposed on a ceramic substrate 402 of the power module 400. For instance, the gate signal lead 410 can be coupled with the patterned metal layer portion 412 via solder, a laser-welded bond, a brazed bond, or a sintered bond, as some examples. As compared to prior approaches, and as with the power module 100 and the power module 200, the DLA approach of FIG. 4 eliminates a wire bond between the gate signal lead 410 and the patterned metal layer portion 412, which can reduce associated parasitic impedance.

As further shown in FIG. 4, a conductive clip 414 electrically couples the patterned metal layer portion 412 with respective gate terminals of the FETs of the semiconductor die 405a, the semiconductor die 405b, the semiconductor die 405c, and the semiconductor die 405b. In this example, the respective conduction path lengths from the gate signal lead 410 and the gate terminals of the semiconductor die 405a and the semiconductor die 405b, as respectively compared with the gate conduction path lengths for the semiconductor die 405c and the semiconductor die 405d, within manufacturing tolerances of an associated assembly process, are a distance D1 of the conductive clip 414. As parasitic impedance of the distance D1 of the conductive clip 414 may be negligible, switching imbalance between the respective transistors of the semiconductor die 405a, the semiconductor die 405b, the semiconductor die 405c, and the semiconductor die 405d can be reduced as compared to prior implementations, or can be effectively eliminated, where any switching imbalance is negligible. That is, the conductive clip 414 can implement substantially electrically balanced signal conduction paths between the patterned metal layer portion 412 (or the gate signal lead 410) and respective gate terminals of the transistors of the semiconductor die 405a, the semiconductor die 405b the semiconductor die 405c, and the semiconductor die 405d.

The power module 400 further includes a conductive clip 424 that is coupled with a source power terminal 420. The conductive clip 424 is further coupled with respective sources terminals of the semiconductor die 405a, the semiconductor die 405b, the semiconductor die 405c, and the semiconductor die 405d. The conductive clip 424 can be coupled with the source power terminal 420, and the semiconductor die 405a, 405b, 405c and 405d using solder, or sintering, as two examples. Such an approach eliminates use of a patterned metal layer portion on the substrate 402 of the power module 400, such as the patterned metal layer portion 222 of the power module 200, or the patterned metal layer portion 322 of the power module 300. This approach can reduce parasitic impedance, as well as facilitate use of a smaller substrate 402 than implementations that include a patterned metal layer portion for connection to, for example, source terminals of parallel-connected FETs. Accordingly, the conductive clip 424 can implement substantially electrically balanced conduction paths from the source power terminal 420 to the respective source terminals of the transistors of the semiconductor die 405a, 405b, 405c and 405d.

The power module 400 also includes a drain power terminal 430 that is coupled, via DLA, with a patterned metal layer portion 432 that is disposed on the ceramic substrate 402. The patterned metal layer portion 432 is coupled with respective drain terminals of the semiconductor die 405a, 405b, 405c and 405d via back sides of the semiconductor die. Accordingly, the drain power terminal 430 and the patterned metal layer portion 432 can implement substantially electrically balanced conduction paths to respective drain terminals of the transistors of the semiconductor die 405a, 405b, 405c and 405d.

FIG. 5 is a diagram that illustrates an example multi-substrate panel 500. In the example, the multi-substrate panel 500 includes a plurality of substrates 502. In this example, a substrate of the plurality of substrates 502 can be used to implement the power module 200 of FIG. 2. That is, the plurality of substrates 502 can be used to implement the ceramic substrate 202 of the power module 200.

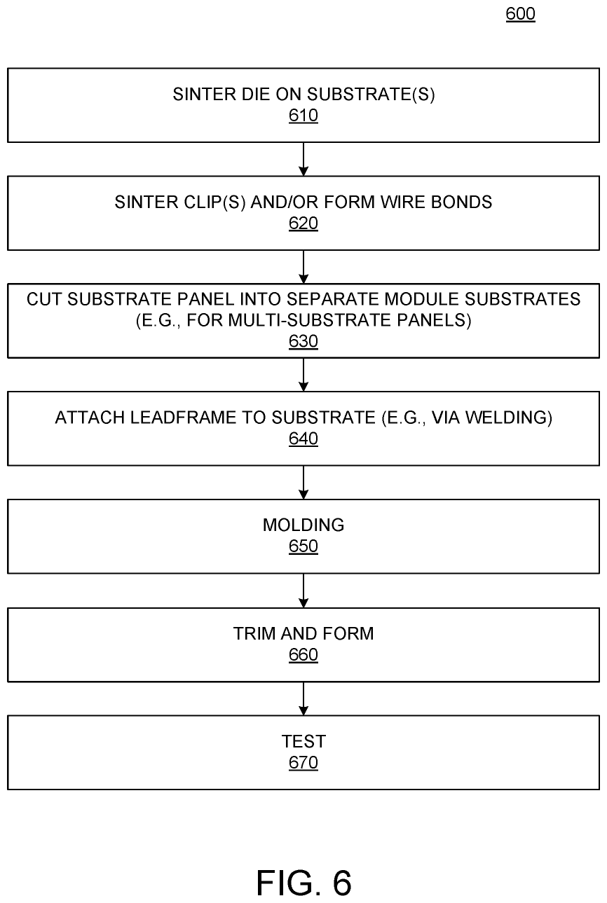

As described below with respect to the assembly method of FIG. 6, the plurality of substrates 502 of the multi-substrate panel 500 can be separated into separate semiconductor devices assemblies (such as separate implementations of the power module 200, for example) as part of an assembly manufacturing process. In this example, each substrate of the plurality of substrates 502 includes a patterned metal layer having a patterned metal layer portion 512, a patterned metal layer portion 522, and a patterned metal layer portion 532, e.g., which can respectively correspond with the patterned metal layer portion 212, the patterned metal layer portion 222 and the patterned metal layer portion 232 of the power module 200 shown in FIG. 2.

FIG. 6 is a flowchart illustrating an example method 600 for producing a multi-chip semiconductor device assembly, such as the example assemblies of FIGS. 2 to 4. The method 600 includes, at block 610, coupling a plurality of die on a substrate, or respective pluralities of semiconductor dies on respective substrates of a panel of substrates, such as the multi-substrate panel 500 of FIG. 5. In this example, the semiconductor die are coupled with their corresponding substrates using a sintering process and sintering material, e.g., a silver-based sintering material. In some implementations, the semiconductor die can be coupled with their corresponding substrates using other approaches, such as solder, epoxy adhesive, eutectic die attach, and so forth.

At block 620, the method 600 includes coupling conductive clips, such as those described herein, with the semiconductor die of block 610 and/or the corresponding substrates, and/or forming wire bonds, such as the wire bond 214a and the wire bond 214b of the power module 200. At block 630, for semiconductor device assemblies produced using panels of substrates, the method 600 includes cutting the substrate panel into individual substrates, e.g., for respective semiconductor device assemblies, such as those described herein. The cutting at block 630 can include laser cutting, saw cutting, and/or plasma cutting, as some examples.

At block 640, the method 600 includes coupling a leadframe to a corresponding substrate, where in the leadframe can include signal leads and power terminals, such as described herein. In some implementation, the operation of block 640 can also include attaching additional conductive clips, such as the conductive clip 424 of the power module 400 coupled between the source power terminal 420 and the respective source terminals of the semiconductor die 405a to 405d. In some implementations, the operation of block 640 can include laser welding the leadframe and/or corresponding conductive clips.

At block 650, the method 600 includes performing a molding process on the semiconductor device assembly (assemblies) being produced. While not shown in FIGS. 2 to 4, the power module 200, the power module 300 and/or the power module 400 can be molded using, e.g., a transfer molding process, to encapsulate portions of the assemblies in an epoxy molding compound. At block 660, a trim and form operation can be performed, which can include trimming tie bars of a leadframe (e.g., to separate individual leads or terminals) and forming, e.g., bending, signal leads and/or power terminals, as appropriate for a particular implementation. At block 670, a functional test can be performed, to test operation of the produced semiconductor device assembly or assemblies.

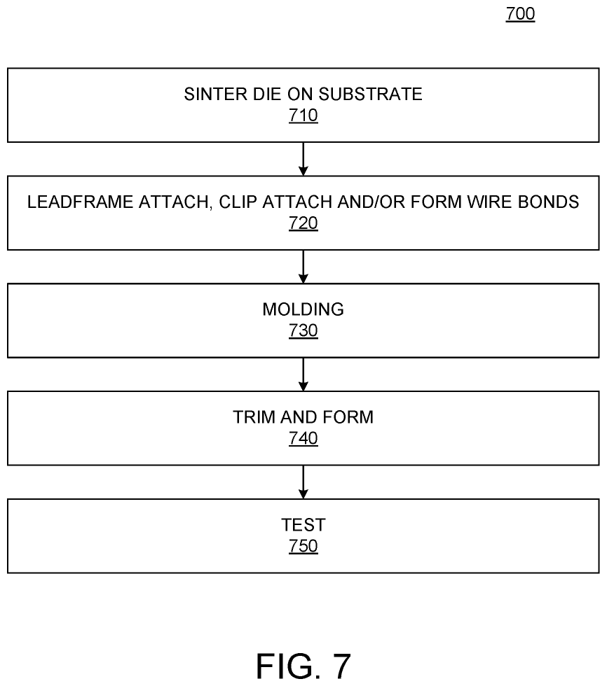

FIG. 7 is a flowchart illustrating another example method 700 for producing a multi-chip semiconductor device assembly, such as the example assemblies of FIGS. 2 to 4. The method 700 includes, at block 710, coupling a plurality of die on a substrate, such as on a portion of a patterned metal layer. In this example, the semiconductor die are coupled with a corresponding substrate using a sintering process and sintering material, e.g., a silver-based sintering material. In some implementations, the semiconductor die can be coupled with the corresponding substrate using other approaches, such as solder, epoxy adhesive, eutectic die attach, and so forth.

At block 720, the method 700 includes attaching a leadframe and/or conductive clips in the semiconductor device assembly (e.g., power module) being produced. As shown in FIG. 7, the operations of block 720 can, in some implementations, include forming wire bonds, such as the wire bond 214a and the wire bond 214b of the power module 200. Leadframe and/or clip attachment at block 720 can include a solder operation, a sinter operation and/or a welding operation, as some examples.

At block 730, the method 700 includes performing a molding process on the semiconductor device assembly (assemblies) being produced. While not shown in FIGS. 2 to 4, the power module 200, the power module 300 and/or the power module 400 can be molded using, e.g., a transfer molding process, to encapsulate portions of the assemblies in an epoxy molding compound. At block 740, a trim and form operation can be performed, which can include trimming tie bars of a leadframe and forming signal leads and or power terminals, as appropriate for a particular implementation. At block 750, a functional test can be performed, to test operation of the semiconductor device assembly.

In a general aspect, a semiconductor device assembly includes a substrate having a patterned metal layer disposed thereon, a first semiconductor die, the first semiconductor die disposed on a first portion of the patterned metal layer, and a second semiconductor die disposed on the first portion of the patterned metal layer. The assembly also includes a first electrical connection electrically coupling a second portion of the patterned metal layer with the first semiconductor die. and a second electrical connection electrically coupling the second portion of the patterned metal layer with the second semiconductor die. The second electrical connection is substantially electrically balanced with the first electrical connection.

Implementations can include one or more of the following feature, alone or in combination. For example, the first electrical connection can include a first bond wire having a first length, and the second electrical connection can include a second bond wire having a second length. The second length can be substantially equal to the first length.

The first electrical connection and the second electrical connection can be implemented by a single conductive clip.

The assembly can include a sintering material respectively electrically coupling the single conductive clip with the second portion of the patterned metal layer, the first semiconductor die, and the second semiconductor die.

The assembly can include a solder material respectively electrically coupling the single conductive clip with the second portion of the patterned metal layer, the first semiconductor die, and the second semiconductor die.

The first semiconductor die can include a first transistor. The second semiconductor die can include a second transistor. The first transistor and the second transistor can be connected in parallel.

The assembly can include a first conductive clip electrically coupling a third portion of the patterned metal layer with a source terminal of the first transistor, and a source terminal of the second transistor. The first electrical connection and the second electrical connection can be implemented by a second conductive clip. The first electrical connection can electrically couple the second portion of the patterned metal layer to a gate terminal of the first transistor, and the second electrical connection can electrically couple the second portion of the patterned metal layer to a gate terminal of the second transistor.

An electrical conduction path between the third portion of the patterned metal layer and the source terminal of the first transistor can be substantially electrically balanced with an electrical conduction path between the third portion of the patterned metal layer and the source terminal of the second transistor.

The assembly can include a third semiconductor die including a third transistor. The third semiconductor die can be disposed on the first portion of the patterned metal layer. The assembly can include a fourth semiconductor die including a fourth transistor. The fourth semiconductor die can be disposed on the first portion of the patterned metal layer. A third electrical connection can electrically couple the second portion of the patterned metal layer with a gate terminal of the third transistor. A fourth electrical connection can electrically couple the second portion of the patterned metal layer with a gate terminal of the third transistor. The third electrical connection and the fourth electrical connection can be, respectively, substantially electrically balanced with the first electrical connection and the second electrical connection.

The first electrical connection, the second electrical connection, the third electrical connection and the fourth electrical connection can be implemented by a single conductive clip.

In another general aspect, a semiconductor device assembly includes a substrate having a patterned metal layer disposed thereon, a first semiconductor die including a first transistor, and a second semiconductor die including a second transistor. The first semiconductor die and the second semiconductor die are respectively disposed on a first portion of the patterned metal layer. The assembly further includes a conductive clip implementing a first electrical connection between a second portion of the patterned metal layer and a gate terminal of the first transistor, and a second electrical connection between the second portion of the patterned metal layer and a gate terminal of the second transistor. The second electrical connection is substantially electrically balanced with the first electrical connection.

Implementations can include one or more of the following feature, alone or in combination. For example, the assembly can include a third semiconductor die including a third transistor, and a fourth semiconductor die including a fourth transistor. The third semiconductor die and the fourth semiconductor die can, respectively, be disposed on the first portion of the patterned metal layer. The conductive clip can implement a third electrical connection electrically coupling the second portion of the patterned metal layer with a gate terminal of the third transistor, and a fourth electrical connection electrically coupling the second portion of the patterned metal layer with a gate terminal of the third transistor. The third electrical connection and the fourth electrical connection can respectively be substantially electrically balanced with the first electrical connection and the second electrical connection.

The assembly can include a sintering material respectively electrically coupling the conductive clip with the second portion of the patterned metal layer, the gate terminal of the first transistor, the gate terminal of the second transistor, the gate terminal of the third transistor, and the gate terminal of the fourth transistor.

The assembly can include a solder material respectively electrically coupling the conductive clip with the second portion of the patterned metal layer, the gate terminal of the first transistor, the gate terminal of the second transistor, the gate terminal of the third transistor; and the gate terminal of the fourth transistor.

The conductive clip can be a first conductive clip, The assembly can include a leadframe including a power terminal, and a second conductive clip. The second conductive clip can implement a plurality of substantially electrically balanced electrical connections including an electrical connection between the power terminal and a source terminal of the first transistor, an electrical connection between the power terminal and a source terminal of the second transistor, an electrical connection between the power terminal and a source terminal of the third transistor, and an electrical connection between the power terminal and a source terminal of the fourth transistor.

The conductive clip can be a first conductive clip, The assembly can include a second conductive clip electrically coupling a third portion of the patterned metal layer with a source terminal of the first transistor, and a source terminal of the second transistor. The second conductive clip can implement a first electrical conduction path between the third portion of the patterned metal layer and the source terminal of the first transistor. and a second electrical conduction path between the third portion of the patterned metal layer and the source terminal of the second transistor. The first electrical conduction path can be substantially electrically balanced with the second electrical conduction path.

In another general aspect, a semiconductor device assembly includes a substrate having a patterned metal layer disposed thereon, a first semiconductor die disposed on a first portion of the patterned metal layer, and a second semiconductor die disposed on the first portion of the patterned metal layer. The first semiconductor die includes a first transistor, and the second semiconductor die includes a second transistor. The assembly also includes a first bond wire implementing a first electrical connection between a second portion of the patterned metal layer and a gate terminal of the first transistor, and a second bond wire implementing a second electrical connection between the second portion of the patterned metal layer and a gate terminal of the second transistor. The second electrical connection is substantially electrically balanced with the first electrical connection.

Implementations can include one or more of the following feature, alone or in combination. For example, the first bond wire can have a first length, and the second bond wire can have a second length. The second length can be substantially equal to the first length.

The assembly can include a conductive clip electrically coupling a third portion of the patterned metal layer with a source terminal of the first transistor. and a source terminal of the second transistor. The conductive clip can implement a first electrical conduction path between the third portion of the patterned metal layer and the source terminal of the first transistor, and a second electrical conduction path between the third portion of the patterned metal layer and the source terminal of the second transistor. The first electrical conduction path can be substantially electrically balanced with the second electrical conduction path.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly comprising:
a substrate having a patterned metal layer disposed thereon;
a first semiconductor die disposed on a first portion of the patterned metal layer;
a second semiconductor die disposed on the first portion of the patterned metal layer;
a first electrical connection electrically coupling a second portion of the patterned metal layer with the first semiconductor die; and
a second electrical connection electrically coupling the second portion of the patterned metal layer with the second semiconductor die, the second electrical connection being substantially electrically balanced with the first electrical connection.

2. The semiconductor device assembly of claim 1, wherein;
the first electrical connection includes a first bond wire having a first length; and
the second electrical connection includes a second bond wire having a second length, the second length being substantially equal to the first length.

3. The semiconductor device assembly of claim 1, wherein the first electrical connection and the second electrical connection are implemented by a single conductive clip.

4. The semiconductor device assembly of claim 3, further comprising a sintering material respectively electrically coupling the single conductive clip with:
the second portion of the patterned metal layer;
the first semiconductor die; and
the second semiconductor die.

5. The semiconductor device assembly of claim 3, further comprising a solder material respectively electrically coupling the single conductive clip with:
the second portion of the patterned metal layer;
the first semiconductor die; and
the second semiconductor die.

6. The semiconductor device assembly of claim 1, wherein:
the first semiconductor die includes a first transistor;
the second semiconductor die includes a second transistor; and
the first transistor and the second transistor are connected in parallel.

7. The semiconductor device assembly of claim 6, further comprising a conductive clip electrically coupling a third portion of the patterned metal layer with:
a source terminal of the first transistor; and
a source terminal of the second transistor.

8. The semiconductor device assembly of claim 7, wherein:
the conductive clip is a first conductive clip;
the first electrical connection and the second electrical connection are implemented by a second conductive clip;
the first electrical connection electrically couples the second portion of the patterned metal layer to a gate terminal of the first transistor; and
the second electrical connection electrically couples the second portion of the patterned metal layer to a gate terminal of the second transistor.

9. The semiconductor device assembly of claim 7, wherein an electrical conduction path between the third portion of the patterned metal layer and the source terminal of the first transistor is substantially electrically balanced with an electrical conduction path between the third portion of the patterned metal layer and the source terminal of the second transistor.

10. The semiconductor device assembly of claim 1, further comprising:
a third semiconductor die including a third transistor, the third semiconductor die being disposed on the first portion of the patterned metal layer;
a fourth semiconductor die including a fourth transistor, the fourth semiconductor die being disposed on the first portion of the patterned metal layer;
a third electrical connection electrically coupling the second portion of the patterned metal layer with a gate terminal of the third transistor; and
a fourth electrical connection electrically coupling the second portion of the patterned metal layer with a gate terminal of the third transistor, the third electrical connection and the fourth electrical connection being, respectively, substantially electrically balanced with the first electrical connection and the second electrical connection.

11. The semiconductor device assembly of claim 10, wherein the first electrical connection, the second electrical connection, the third electrical connection and the fourth electrical connection are implemented by a single conductive clip.

12. A semiconductor device assembly comprising:
a substrate having a patterned metal layer disposed thereon;
a first semiconductor die including a first transistor, the first semiconductor die being disposed on a first portion of the patterned metal layer;
a second semiconductor die including a second transistor, the second semiconductor die being disposed on the first portion of the patterned metal layer; and
a conductive clip implementing:
a first electrical connection between a second portion of the patterned metal layer and a gate terminal of the first transistor; and
a second electrical connection between the second portion of the patterned metal layer and a gate terminal of the second transistor, the second electrical connection being substantially electrically balanced with the first electrical connection.

13. The semiconductor device assembly of claim 12, further comprising:
a third semiconductor die including a third transistor, the third semiconductor die being disposed on the first portion of the patterned metal layer; and
a fourth semiconductor die including a fourth transistor, the fourth semiconductor die being disposed on the first portion of the patterned metal layer,
the conductive clip further implementing:
a third electrical connection electrically coupling the second portion of the patterned metal layer with a gate terminal of the third transistor; and
a fourth electrical connection electrically coupling the second portion of the patterned metal layer with a gate terminal of the third transistor, the third electrical connection and the fourth electrical connection respectively being substantially electrically balanced with the first electrical connection and the second electrical connection.

14. The semiconductor device assembly of claim 13, further comprising a sintering material respectively electrically coupling the conductive clip with:
the second portion of the patterned metal layer;
the gate terminal of the first transistor;
the gate terminal of the second transistor;
the gate terminal of the third transistor; and
the gate terminal of the fourth transistor.

15. The semiconductor device assembly of claim 13, further comprising a solder material respectively electrically coupling the conductive clip with:
the second portion of the patterned metal layer;
the gate terminal of the first transistor;
the gate terminal of the second transistor;
the gate terminal of the third transistor; and
the gate terminal of the fourth transistor.

16. The semiconductor device assembly of claim 13, wherein the conductive clip is a first conductive clip, the semiconductor device assembly further comprising:
a leadframe including a power terminal; and
a second conductive clip implementing a plurality of substantially electrically balanced electrical connections including:
an electrical connection between the power terminal and a source terminal of the first transistor;
an electrical connection between the power terminal and a source terminal of the second transistor;
an electrical connection between the power terminal and a source terminal of the third transistor; and
an electrical connection between the power terminal and a source terminal of the fourth transistor.

17. The semiconductor device assembly of claim 12, wherein the conductive clip is a first conductive clip, the semiconductor device assembly further comprising:
a second conductive clip electrically coupling a third portion of the patterned metal layer with:
a source terminal of the first transistor; and
a source terminal of the second transistor, the second conductive clip implementing:
a first electrical conduction path between the third portion of the patterned metal layer and the source terminal of the first transistor; and
a second electrical conduction path between the third portion of the patterned metal layer and the source terminal of the second transistor,
the first electrical conduction path being substantially electrically balanced with the second electrical conduction path.

18. A semiconductor device assembly comprising:
a substrate having a patterned metal layer disposed thereon;
a first semiconductor die including a first transistor, the first semiconductor die being disposed on a first portion of the patterned metal layer;
a second semiconductor die including a second transistor, the second semiconductor die being disposed on the first portion of the patterned metal layer;
a first bond wire implementing a first electrical connection between a second portion of the patterned metal layer and a gate terminal of the first transistor; and
a second bond wire implementing a second electrical connection between the second portion of the patterned metal layer and a gate terminal of the second transistor, the second electrical connection being substantially electrically balanced with the first electrical connection.

19. The semiconductor device assembly of claim 18, wherein;
the first bond wire has a first length; and
the second bond wire has a second length, the second length being substantially equal to the first length.

20. The semiconductor device assembly of claim 12, the semiconductor device assembly further comprising:
a conductive clip electrically coupling a third portion of the patterned metal layer with:
a source terminal of the first transistor; and
a source terminal of the second transistor, the conductive clip implementing:
a first electrical conduction path between the third portion of the patterned metal layer and the source terminal of the first transistor; and
a second electrical conduction path between the third portion of the patterned metal layer and the source terminal of the second transistor,
the first electrical conduction path being substantially electrically balanced with the second electrical conduction path.
